(19) United States
(12) Patent Application Publication
(10) Pub. No.: US 2025/0142792 A1
(43) Pub. Date: May 1, 2025

(54) CONTROL DEVICE, CONTROL SYSTEM AND CONTROL METHOD

(71) Applicant: MITSUBISHI HEAVY INDUSTRIES, LTD., Tokyo (JP)

(72) Inventors: Tomohiko SANADA, Tokyo (JP); Ryo IIDA, Tokyo (JP)

(21) Appl. No.: 18/836,387

(22) PCT Filed: Sep. 28, 2022
(86) PCT No.: PCT/JP2022/036057

§ 371 Date: Aug. 7, 2024

(30) Foreign Application Priority Data
Feb. 15, 2022 (JP) 2022-020984

(51) Int. Cl. H05K 7/20; H02M 1/00; H02M 1/32

(52) U.S. Cl. CPC H05K 7/20945; H02M 1/0009; H02M 1/327; H05K 7/20909

(57) ABSTRACT

Provided is a control device comprising a control unit that controls respective flow rates of a refrigerant distributed to respective power converters each having a power module within a range in which each predetermined temperature of the plurality of power converters does not exceed each temperature management values.

### TECHNICAL FIELD

The present disclosure relates to a control device, a control system, and a control method. Priority is claimed on Japanese Patent Application No. 2022-020984, filed Feb. 15, 2022, the content of which is incorporated herein by reference.

### BACKGROUND ART

PTL 1 discloses the following electronic component cooling device. That is, the electronic component cooling device disclosed in PTL 1 includes a cooler that cools an electronic component, a refrigerant temperature acquisition unit that acquires a temperature of a refrigerant, a refrigerant flow rate acquisition unit that acquires a flow rate of the refrigerant, a heat loss estimation unit that estimates a heat loss in the electronic component, a loss threshold calculation unit that calculates an appropriate upper limit threshold of the beat loss in the electronic component based on the refrigerant temperature and the refrigerant flow rate, and a refrigerant flow rate control unit that controls the flow rate of the refrigerant. The refrigerant flow rate control unit increases the flow rate of the refrigerant flowing through the cooler when the estimated heat loss exceeds the appropriate upper limit threshold.

### CITATION LIST

### Patent Literature

[PTL 1] Japanese Unexamined Patent Application Publication No. 2020-92263

### SUMMARY OF INVENTION

### Technical Problem

However, PTL 1 does not show how to deal with a case where there are a plurality of cooling targets.

An object of the present disclosure is to provide a control device, a control system, and a control method capable of appropriately cooling a plurality of power converters.

### Solution to Problem

In order to solve the above problem, a control device according to the present disclosure includes a control unit that controls each flow rate of a refrigerant distributed to each of a plurality of power converters each including a power module within a range in which each predetermined temperature of the power converters does not exceed each temperature management value.

A control method according to the present disclosure includes controlling each flow rate of a refrigerant distributed to each of a plurality of power converters each including a power module within a range in which each predetermined temperature of the power converters does not exceed each temperature management value.

### Advantageous Effects of Invention

According to the control device, the control system, and the control method of the present disclosure, it is possible to appropriately cool a plurality of power converters.

### BRIEF DESCRIPTION OF DRAWINGS

FIG. 1 is a diagram illustrating a configuration example of a control system according to an embodiment of the present disclosure.

FIG. 2 is a block diagram illustrating a configuration example of a power converter according to an embodiment of the present disclosure.

FIG. 3 is a perspective view showing a configuration example of a power converter according to an embodiment of the present disclosure.

FIG. 4 is a perspective view illustrating a configuration example of a power converter according to an embodiment of the present disclosure, and illustrates a state in which a cover is removed.

FIG. 5 is a perspective view illustrating a configuration example of the power converter according to the embodiment of the present disclosure, and illustrates a state viewed from below.

FIG. 6 is a block diagram illustrating a functional configuration example of a control device according to an embodiment of the present disclosure.

FIG. 7 is a schematic diagram for explaining an operation example of the control system according to the embodiment of the present disclosure.

FIG. 8 is a schematic diagram for explaining an operation example of the control system according to the embodiment of the present disclosure.

FIG. 9 is a schematic diagram for explaining an operation example of the control system according to the embodiment of the present disclosure.

FIG. 10 is a schematic diagram for explaining an operation example of the control device according to the embodiment of the present disclosure.

FIG. 11 is a flowchart illustrating an operation example of the control device according to the embodiment of the present disclosure.

FIG. 12 is a schematic block diagram illustrating a configuration of a computer according to at least one embodiment.

### DESCRIPTION OF EMBODIMENTS

### First Embodiment

### Control System

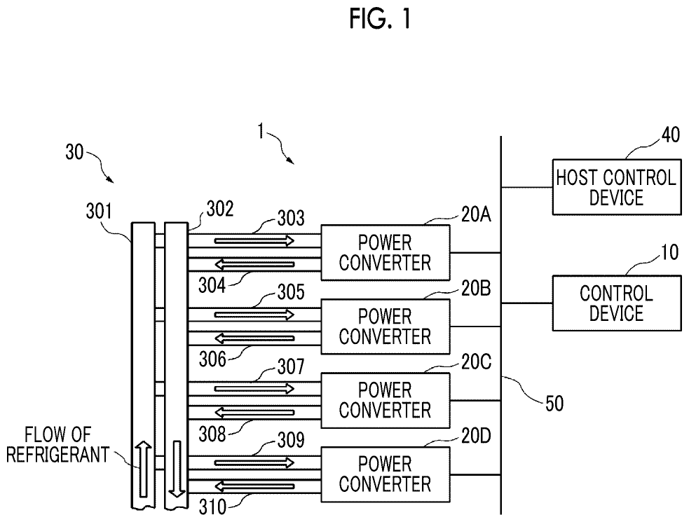

Hereinafter, a control device, a control system, and a control method according to an embodiment of the present disclosure will be described with reference to FIGS. 1 to 11. In the drawings, the same or corresponding components are denoted by the same reference numerals, and the description thereof will not be repeated.

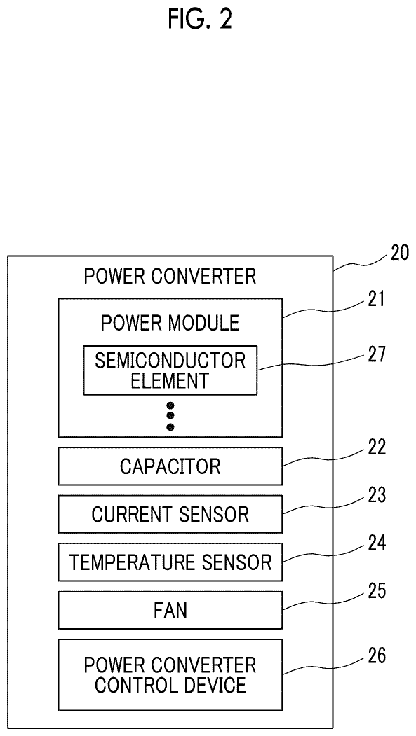

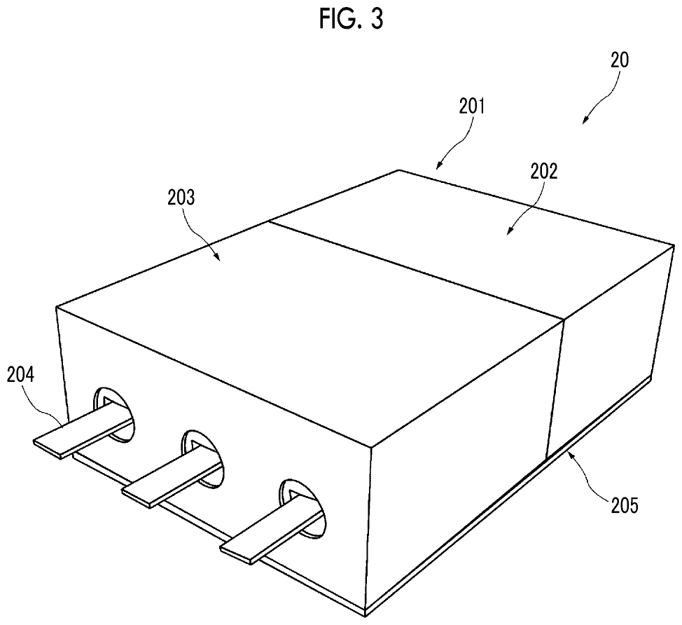

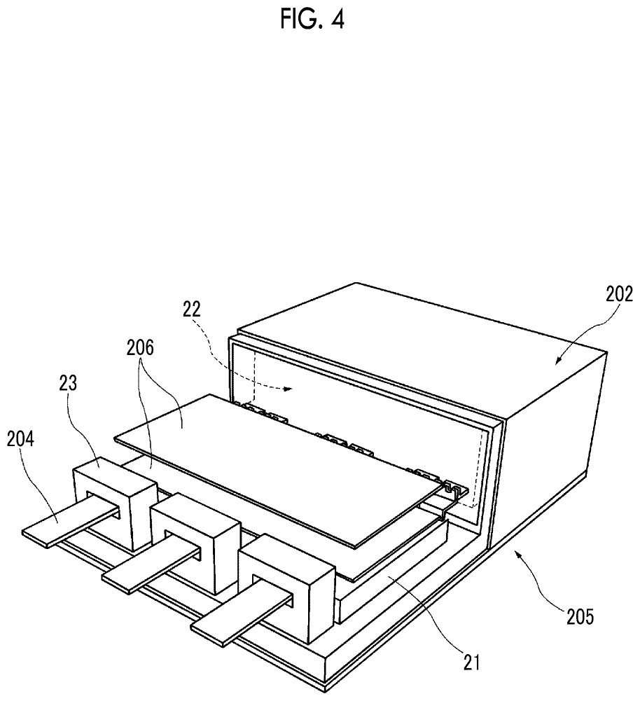

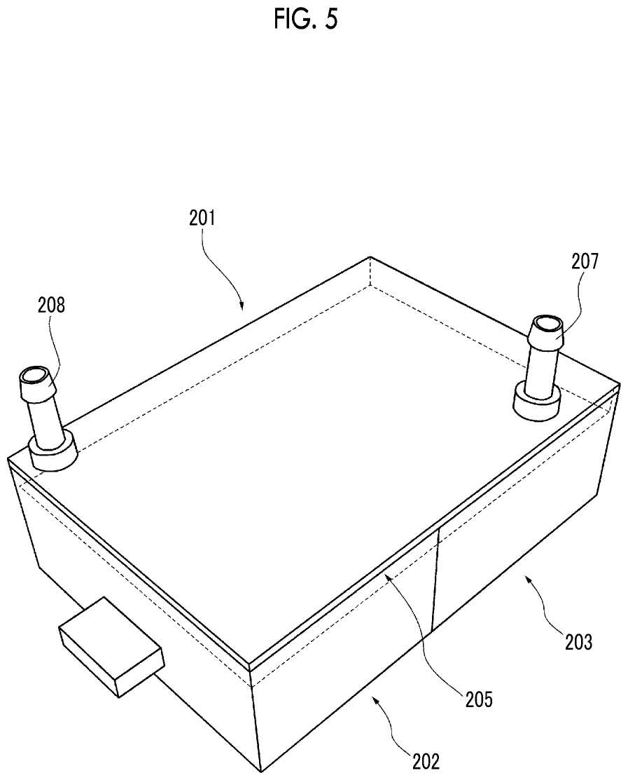

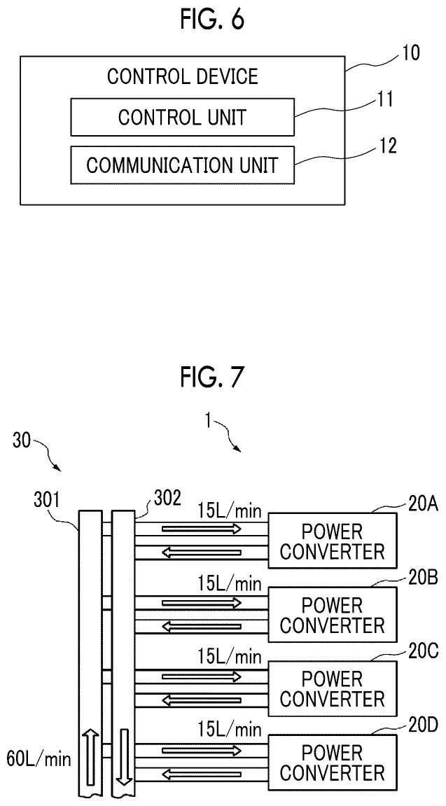

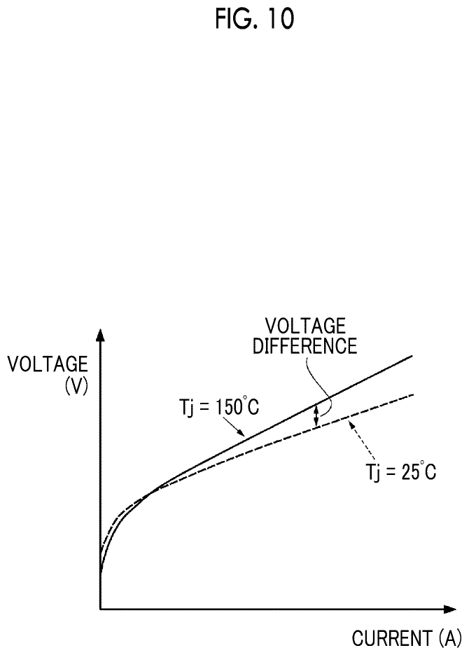

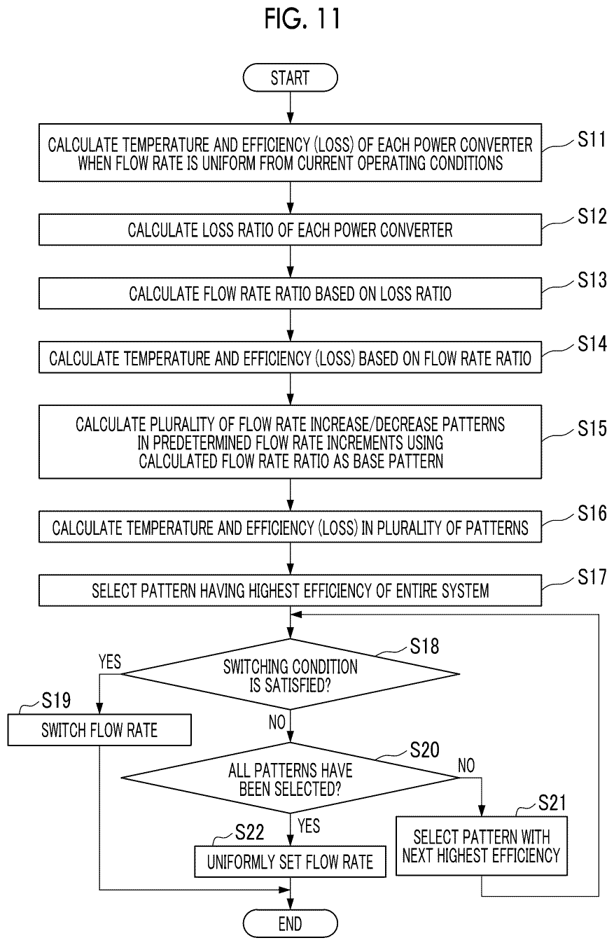

FIG. 1 is a diagram illustrating a configuration example of a control system according to an embodiment of the present disclosure. FIG. 2 is a block diagram illustrating a configuration example of a power converter according to an embodiment of the present disclosure. FIG. 3 is a perspective view illustrating a configuration example of a power converter according to an embodiment of the present disclosure. FIG. 4 is a perspective view illustrating a configuration example of the power converter according to the embodiment of the present disclosure, and illustrates a state in which a cover is removed. FIG. 5 is a perspective view illustrating a configuration example of the power converter according to the embodiment of the present disclosure, and illustrates a state viewed from below. FIG. 6 is a block diagram illustrating a functional configuration example of a control device according to an embodiment of the present disclosure. FIGS. 7 to 9 are schematic diagrams for describing an operation example of the control system according to the embodiment of the present disclosure. FIG. 10 is a schematic diagram for describing an operation example of the control device according to the embodiment of the present disclosure. FIG. 11 is a flowchart illustrating an operation example of the control device according to the embodiment of the present disclosure.

As illustrated in FIG. 1, a control system I according to an embodiment of the present disclosure includes a control device 10, four power converters 20A to 20D, a cooling device 30, a host control device 40, and a communication line 50. The control system 1 is, for example, a power system used in a mobile object such as an automobile or a ship, a smart grid, or the like. For example, the control system 1 converts DC power supplied from a battery, a power generation device, or the like into DC power or AC power of a predetermined voltage or current and outputs the DC power or the AC power. The load in this case is, for example, an electrical product such as a motor, lighting equipment, or air conditioning equipment. The control system 1 converts, for example, AC or DC power supplied from the outside into DC power of a predetermined voltage or current and outputs the DC power. The load in this case is, for example, a battery. However, these are merely examples, and the application of the control system 1 is not limited thereto.

### Power Converter

The power converters 20A to 20D illustrated in FIG. 1 have conversion functions of, for example, converting input DC power into AC power and outputting the AC power, converting AC power into DC power, stepping up or stepping down the voltage of DC power, and bidirectionally converting AC power and DC power. The power converters 20A to 20D are cooled by the refrigerant supplied from the cooling device 30. The power converters 20A to 20D may have different conversion functions, or some or all of them may have the same conversion function. For example, the power converters 20A to 20D are used as a three-phase inverter for driving a motor of an electric vehicle, a charger for an in-vehicle battery, a three-phase inverter for driving a small motor such as a pump or a compressor, or a DC (direct current)/DC converter for other electrical components. In the example shown in FIG. 1, the power converters 20A to 20D each control, for example, output power (and/or output voltage or output current) in accordance with an output command from the host control device 40 (or control device 10). For example, depending on the operation mode of the control system 1, the power converters 20A to 20D move, do not move, or have a difference in the magnitude of the load. The power converters 20A to 20D are collectively referred to as a power converter 20. Further, the number of power converters 20 is not limited to four, and may be plural.

FIG. 2 shows a configuration example of the power converter 20. In the example illustrated in FIG. 2, the power converter 20 includes a power module 21, a capacitor 22, a current sensor 23, a temperature sensor 24, a fan 25, and a power converter control device 26. The number of each of the power module 21, the capacitor 22, the current sensor 23, the temperature sensor 24, and the fan 25 may be one, or some or all of the power module 21, the capacitor 22, the current sensor 23, the temperature sensor 24, and the fan 25 may be plural. For example, some configurations such as the temperature sensor 24 and the fan 25 may not be provided.

The power module 21 includes a plurality of semiconductor elements 27. The semiconductor element 27 is, for example, a power semiconductor element such as a transistor or a diode. The transistor is, for example, a power transistor such as an insulated gate bipolar transistor (IGBT) or a metal oxide semiconductor field effect transistor (MOSFET). However, there is no limitation. When the semiconductor element 27 is a transistor, for example, the power converter control device 26 performs on/off control at a predetermined switching frequency.

The capacitor 22 is a smoothing capacitor or a DC link capacitor, and smooths, for example, a ripple voltage generated by a switching operation of the power module 21. The capacitor 22 removes, for example, a high-frequency component or the like from the external power input to the power converter 20. As the capacitor 22 in the present embodiment, for example, a film capacitor or the like can be exemplified. The power converter 20 of the present embodiment includes, for example, a plurality of capacitors 22.

The current sensor 23 detects a direct current or an alternating current input to the power module 21 or output from the power module 21, and outputs the detection result to the power converter control device 26. The temperature sensor 24 detects the temperature in the housing of the power converter 20 and outputs the detection result to the power converter control device 26. The fan 25 circulates air in the housing of the power converter 20. The wind speed of the fan 25 is controlled by, for example, the power converter control device 26.

The power converter control device 26 transmits and receives predetermined information to and from the control device 10 and the host control device 40 via the communication line 50. In addition, the power converter control device 26 inputs a detection result of the current sensor 23, a detection result of the temperature sensor 24, a voltage of each unit, and the like, and controls an operation of the semiconductor element 27 of the power module 21 based on an output command or the like received from the host control device 40 or the like. The power converter control device 26 transmits the detection result of the current sensor 23 and the detection result of the temperature sensor 24 to the control device 10 and the like. The power converter control device 26 switches the switching frequency of the semiconductor element 27 of the power module 21 based on the switching frequency switching command received from the control device 10.

Next, a structural configuration example of the power converter 20 will be described with reference to FIGS. 3 to 5. The power module 21 shown in FIGS. 3 to 5 is a module in which a plurality of power semiconductor elements (semiconductor elements 27) such as surface-mounted power MOSFETs or IGBTs are mounted on a circuit board. FIGS. 3 to 5 illustrate the power module 21 capable of outputting three-phase power.

As shown in FIGS. 3 to 5, the power converter 20 of the present embodiment includes a housing 201, a capacitor 22, a power module 21, a control board 206, a bus bar 204, and a current sensor 23.

The housing 201 is a box for accommodating the capacitor 22, the power module 21, the control board 206, and the current sensor 23. The housing 201 can be formed of, for example, a metal, a synthetic resin, or the like having high thermal conductivity. The housing 201 includes a capacitor accommodating portion 202, a cover portion 203, and a refrigerant flow path forming portion 205.

The refrigerant flow path forming portion 205 forms a flow path through which the refrigerant flows. The refrigerant inlet 207 and the refrigerant outlet 208 communicate the inside and the outside of the refrigerant flow path forming portion 205. That is, when the refrigerant flows in from the refrigerant inlet 207, the refrigerant flows through the flow path in the refrigerant flow path forming portion 205 and is then discharged from the refrigerant outlet 208 to the outside of the refrigerant flow path forming portion 205.

The capacitor accommodating portion 202 accommodates the capacitor 22. The capacitor accommodating portion 202 is formed integrally with a part of the refrigerant flow path forming portion 205. The cover portion 203 defines a power module housing space for housing at least the power module 21 together with the capacitor accommodating portion 202 and the remaining portion of the refrigerant flow path forming portion 205 where the capacitor accommodating portion 202 is not formed. Here, the remaining portion of the refrigerant flow path forming portion 205 is a portion of the refrigerant flow path forming portion 205 excluding a portion formed integrally with the capacitor accommodating portion 202. The cover portion 203 is configured to be attachable to and detachable from the refrigerant flow path forming portion 205 and the capacitor accommodating portion 202. In the refrigerant flow path forming portion 205 in the present embodiment, a part of the refrigerant flow path forming portion 205 formed integrally with the capacitor accommodating portion 202 cools the capacitor, and the remaining part of the refrigerant flow path forming portion 205 cools the power module 21.

The power module 21 includes a cooling fin (not shown) for cooling the power semiconductor element. The cooling fin is fixed to a back surface of the circuit board facing a side opposite to a mounting surface on which the power semiconductor element is mounted. The cooling fin is electrically insulated from the circuit board, and heat generated from the power semiconductor element is transferred to the cooling fin. At least a part of the cooling fin is located in the flow path of the refrigerant flow path forming portion 205. That is, heat can be indirectly exchanged between the power semiconductor element and the refrigerant via the cooling fin, the circuit board, and the like.

### Cooling Device

The cooling device 30 illustrated in FIG. 1 includes pipes 301 to 310, and a pump, a heat exchanger, a plurality of control valves, one or a plurality of refrigerant temperature sensors, a plurality of flow rate sensors, and the like, which are not illustrated. In FIG. 1, the flow of the refrigerant is indicated by white arrows. The cooling device 30 may or may not include a device that variably controls the temperature of the refrigerant. The refrigerant for cooling power converter 20A flows in from pipe 301 through pipe 303 and flows out from pipe 304 to pipe 302. The refrigerant for cooling power converter 20B flows in from pipe 301 through pipe 305, and flows out from pipe 306 to pipe 302. The refrigerant for cooling power converter 20C flows in from pipe 301 through pipe 307, and flows out from pipe 308 to pipe 302. The refrigerant for cooling power converter 20D flows in from pipe 301 through pipe 309 and flows out from pipe 310 to pipe 302. For example, the pipe 303 or the pipe 304 is provided with a control valve (not shown) for controlling the flow rate of the refrigerant and a flow rate sensor (not shown) for measuring the flow rate of the refrigerant. For example, the pipe 305 or the pipe 306 is provided with a control valve (not shown) for controlling the flow rate of the refrigerant and a flow rate sensor (not shown) for measuring the flow rate of the refrigerant. For example, the pipe 307 or the pipe 308 is provided with a control valve (not shown) for controlling the flow rate of the refrigerant and a flow rate sensor (not shown) for measuring the flow rate of the refrigerant. For example, the pipe 309 or the pipe 310 is provided with a control valve (not shown) for controlling the flow rate of the refrigerant and a flow rate sensor (not shown) for measuring the flow rate of the refrigerant. For example, the pipe 301 or the pipe 302 is provided with a refrigerant temperature sensor (not shown) that measures the temperature of the refrigerant. These control valves are controlled by the control device 10. The detection result of the refrigerant temperature sensor is output to the control device 10. When the cooling device 30 includes a device that variably controls the temperature of the refrigerant, the cooling device 30 variably controls the temperature of the refrigerant in accordance with a control command from the control device 10. The device for variably controlling the temperature includes, for example, a compressor, a heat exchanger, and the like.

### Host Control Device

The host control device 40 illustrated in FIG. 1 outputs an output command, which is information indicating a required value of output power, to each power converter 20 according to, for example, an operation mode of each load of the power converter 20. For example, when the load of the power converter 20 is a motor, the output command is information including a value of power to be output to the motor. The output command may indicate not only the output power (and/or the output voltage or the output current) but also the conversion efficiency. The output command may include, for example, an instruction to suppress the output and prioritize the efficiency according to the remaining capacity of the battery when the motor or the like is driven by the battery. In this case, for example, the output command can include contents such as controlling the output power within a range from a first value to a second value (larger than the first value) and controlling the efficiency as high as possible.

### Control Device

The control device 10 can be configured using, for example, a computer such as a microcomputer, a peripheral circuit or a peripheral device of the computer, and the like. As illustrated in FIG. 6, the control device 10 includes a control unit 11 and a communication unit 12 as a functional configuration configured by a combination of hardware such as a computer and software such as a program executed by the computer.

The control unit 11 controls each flow rate of the refrigerant distributed to each power converter 20 within a range in which each predetermined temperature of the plurality of power converters 20 each including the power module 21 does not exceed each temperature management value. For example, the control unit 11 controls each flow rate according to each output of each power converter 20. Alternatively, for example, the control unit 11 controls each flow rate according to each efficiency of each power converter 20. The flow rate control according to the efficiency will be described later. The predetermined temperature is a temperature of each part in the power converter 20, and is, for example, a junction temperature (joint portion temperature) of the semiconductor element 27 of the power module 21, a temperature of the capacitor 22, or a temperature of the current sensor 23. The temperature management value is a value obtained by adding a predetermined margin to the maximum allowable temperature of each part.

FIG. 7 shows a state in which the flow rate of the refrigerant to each power converter 20 is uniformly controlled under the control of the control unit 11. In this case, the total flow rate of the refrigerant is 60 L/min, and the flow rate of the refrigerant to each power converter 20 is uniformly 15 L/min.

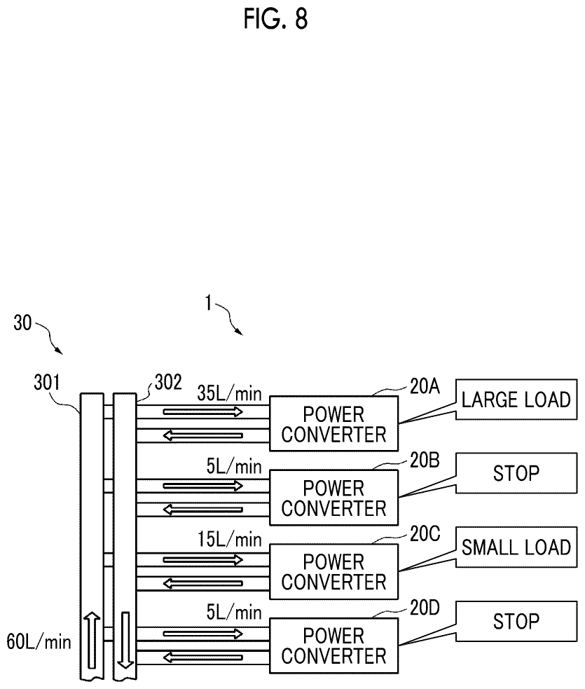

FIG. 8 illustrates an example in which the load of the power converter 20A is relatively large, the power converter 20B is in the stopped state, the load of the power converter 20C is relatively small, and the power converter 20D is in the stopped state. In this case, the control unit 11 controls the above-described control valves (not shown) so that, for example, the flow rate of the refrigerant to the power converter 20A is 35 L/min, the flow rate of the refrigerant to the power converter 20B is 5 L/min, the flow rate of the refrigerant to the power converter 20C is 15 L/min, and the flow rate of the refrigerant to the power converter 20D is 5 L/min. The control unit 11 may instruct the value of the flow rate itself to each control valve, or may instruct the opening degree of the valve to each control valve based on the value of the flow rate detected by the flow rate sensor.

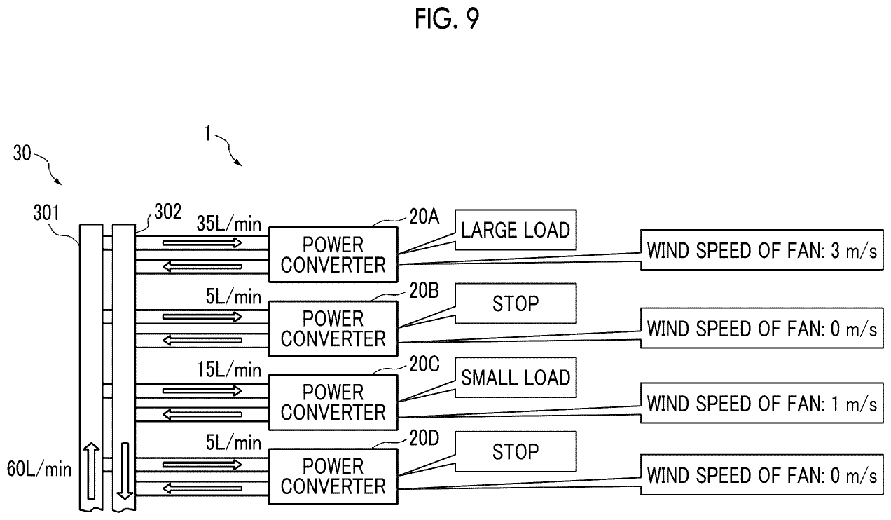

FIG. 9 illustrates an example in which the control unit 11 controls the wind speed of the fan 25 in addition to the flow rate of the refrigerant. In the power converter 20, the power module 21 is hardly affected by the ambient temperature, and the influence of cooling by the refrigerant is dominant. On the other hand, in the capacitor 22, the current sensor 23, and the like, the influence of cooling by the refrigerant is not dominant, and the temperature in the power converter 20 may be a thermal problem. Therefore, the control unit 11 lowers the temperature of the capacitor 22 and the current sensor 23 by controlling the flow rate and the wind speed of the fan 25. The state of the load of each power converter 20 is the same as that in the example of FIG. 8. In the example illustrated in FIG. 9, the control unit 11 controls the fans 25 such that the wind speed of the fan 25 of the power converter 20A is 3 m/s, the wind speed of the fan 25 of the power converter 20B is 0 m/s, the wind speed of the fan 25 of the power converter 20C is 1 m/s, and the wind speed of the fan 25 of the power converter 20D is 0 m/s.

For example, when the power converter 20 includes the current sensor 23, the fan 25 that is an example of the forced air cooling device, and the temperature sensor 24 that detects the temperature in the housing of the power converter 20, the predetermined temperature includes the temperature of the current sensor 23. The control unit 11 can control the flow rate and the wind speed of the fan 25 based on the ambient temperature detected by the temperature sensor 24 and the operating state of the current sensor 23. The operation state of the current sensor 23 is indicated by whether or not the current detected by the current sensor 23 flows, and the magnitude of the current when the current flows.

For example, when the power converter 20 includes the capacitor 22, the predetermined temperature includes the temperature of the capacitor 22. The control unit 11 can control the flow rate based on the loss of the capacitor 22 and the temperature of the refrigerant, and can control the wind speed of the fan 25 based on the ambient temperature.

The communication unit 12 illustrated in FIG. 6 transmits and receives predetermined information to and from the host control device 40, each power converter 20, and the cooling device 30.

### Flow Rate Control According to Efficiency

As described above, the control unit 11 controls each flow rate of the refrigerant distributed to each power converter 20 within a range in which each predetermined temperature of the power converter 20 does not exceed each temperature management value. At this time, the control unit 11 controls each flow rate according to each efficiency of each power converter 20, for example.

Hereinafter, a case where the predetermined temperature is the junction temperature of the semiconductor element 27 of the power module 21 will be described as an example. The junction temperature Tj can be calculated by the following equation.

Tj=loss×thermal resistance+refrigerant temperature

The loss depends on the voltage, the flowing current, the switching frequency, and the like when the semiconductor element 27 is turned on. Here, the voltage at the time of ON corresponds to a voltage corresponding to the ON resistance or a saturation voltage. That is, the voltage at the time of ON corresponds to the drain-source voltage or the collector-emitter voltage at the time of energization. The energization current is a value based on the output command and cannot be changed by the control unit 11. As for the voltage at the time of ON, the minimum value of the voltage at the time of ON is a value corresponding to the characteristics of the semiconductor element 27 when appropriate driving is performed. Therefore, the control unit 11 cannot further reduce the voltage in the ON state. However, the voltage at the time of ON bas temperature dependency.

FIG. 10 shows the temperature dependence of the voltage when the semiconductor element 27 is on. The horizontal axis represents the energization current, and the vertical axis represents the voltage at the time of ON. FIG. 10 shows a comparison between the case where Tj is 150° C., and the case where Tj is 25° C. As shown as a voltage difference in FIG. 10, since there is a voltage difference between the case where Tj is 150° C., and the case where Tj is 25° C., the loss at Tj of 150° C. is larger than the loss at Tj of 25° C. Therefore, when estimating the junction temperature Tj, the control unit 11 of the present embodiment estimates the junction temperature Tj using the above calculation formula based on the temperature of the refrigerant, the thermal resistance of the power module 21, and the loss of the power module 21 in consideration of the temperature dependency.

On the other hand, the switching frequency affecting the loss is a factor changed by the control unit 11.

Next, the thermal resistance is a value indicating difficulty in transmitting temperature or a value indicating difficulty in flowing heat in heat transfer occurring when heat is applied to an object, and the unit is (K/W) or (° C./W). In the case of the power module 21, the thermal resistance changes according to, for example, the material and structure of a member interposed between the cooling fin and the joint portion in the semiconductor element 27 and the flow rate of the refrigerant. The material and structure cannot be controlled by the control unit 11. On the other hand, the control unit 11 can control the flow rate.

When the cooling device 30 includes a device that variably controls the temperature of the refrigerant, the control unit 11 can control the refrigerant temperature.

As described above, when the control unit 11 controls the junction temperature Tj of the power module 21 of the power converter 20 so as not to exceed the temperature management value of the junction temperature Tj, the control unit 11 can control the switching frequency, the flow rate of the refrigerant, and the temperature of the refrigerant among the elements that determine Tj. However, the temperature of the refrigerant is limited to a case where the cooling device 30 includes a device that variably controls the temperature of the refrigerant.

Since the loss has temperature dependence, the efficiency of the power module 21 can be improved by lowering the junction temperature Tj.

Therefore, the control unit 11 controls the flow rate of the refrigerant to each power converter 20 so as to satisfy the following two control conditions.

Control condition 1: Variable elements (switching frequency, flow rate, and refrigerant temperature) are changed so as not to exceed the temperature management value of the power module 21. Control of the flow rate and the like is based on the premise that the power module 21 is controlled so as not to be thermally destroyed.

Control condition 2: By using the fact that the loss of the power module 21 has temperature dependence as described with reference to FIG. 10, the flow rate to the power converter 20 that can reduce the loss as a whole by increasing the flow rate is increased, and the flow rate to the power converter 20 that cannot reduce the loss as a whole even if the flow rate is increased is decreased. Here, the overall loss means the sum of losses of the power converters 20.

That is, the control condition 2 is a condition for performing control to pursue high efficiency of the entire system. The control condition 2 may not be intended to reduce the loss as a whole, but may be intended to reduce the loss of some of the power converters 20.

For the control condition 2, the control unit 11 first calculates each loss of the power converters 20A to 20D from the result of the temperature estimation to calculate the total system loss. Next, the control unit 11 allocates the flow rate based on the current total loss and each loss, and calculates the efficiency of each power converter 20 so as to further increase the efficiency. In the specific example described with reference to FIG. 7, the current total flow rate is 60 L/min, and the upper limit of the total flow rate is not changed. However, the flow rate control is performed on each power converter 20, and the flow rate is controlled to be intensively cooled on the power converter 20 whose efficiency is increased when the power converter 20 is further cooled.

Although the power module 21 has been described as an example, the same can be applied to the capacitor 22 and the current sensor 23. Since the wind speed control by the fan 25 is also added to them, parameters of the ambient temperature and the wind speed (flow velocity) are added. As a whole, the first purpose is the control condition 1 so that the temperature falls within the temperature management value, and the second purpose is to achieve high efficiency as a system.

### Operation Example of Control Device 10

Next, an operation example of the control device 10 (control unit 11) will be described with reference to FIG. 11. The processing illustrated in FIG. 11 is repeatedly executed in a predetermined cycle. When the processing shown in FIG. 11 is started, the control unit 11 calculates the temperature and efficiency (loss) of each power converter 20 when the flow rate is uniform from the current operating conditions (step S11). Next. the control unit 11 calculates a loss ratio of each power converter 20 (step S12). Next, the control unit 11 calculates the flow rate ratio based on the loss ratio (step S13).

For example, in the example shown in FIG. 7, in step S11, the flow rates of the four power converters 20A to 20D are uniformly set to 15 L/min for the respective power converters 20. For example, when the loss ratio is A:B:C:D::4:3:2:1 in step S12. the flow rate is determined to be 24:18:12:6 in step S13 when the total flow rate is 60 L/min. Note that A, B, C, and D represent respective losses or respective flow rates of the power converters 20A to 20D.

Next, the control unit 11 calculates a plurality of flow rate increase/decrease patterns in predetermined flow rate increments using the calculated flow rate ratio as a base pattern (step $15). In step S15, for example, the flow rate step of each power converter 20 is set to 0.5 L/min, the flow rate calculation result obtained in step S13 is set as (1) base pattern (24:18:12:6), and the following six patterns are obtained. (2) The flow rate of A is decreased by 1.5 L/min and the flow rates other than A are decreased by 0.5 L/min; (3) the flow rate of A is increased by 3.0 L/min and the flow rates other than A are decreased by 1.0 L/min; (4) the flow rate of A is increased by 4.5 L/min and the flow rates other than A are decreased by 1.5 L/min; (5) the flow rate of A is decreased by 1.5 L/min and the flow rates other than A are increased by 0.5 L/min; (6) the flow rate of A is decreased by 3.0 L/min and the flow rates other than A are increased by 1.0 L/min; and (7) the flow rate of A is decreased by 4.5 L/min and the flow rates other than A are increased by 1.5 L/min.

Next, the control unit 11 calculates the temperature and the efficiency (loss) in a plurality of patterns (step S16). Next, the control unit 11 selects a pattern having the highest efficiency of the entire system (step S17).

Next, the control unit 11 determines whether or not a predetermined switching condition is satisfied (step S18). The switching condition is, for example, that an effect of improving the system efficiency by a predetermined value or more can be expected as compared with a case where the flow rate is uniform, and a predetermined temperature of each power converter 20 is within a temperature management value. The value of the improvement effect of the system efficiency equal to or more than the predetermined value can be, for example, 1 kW or more, but is not limited thereto. The predetermined value is, for example, a value at which there is a possibility that the benefit of switching the flow rate does not exceed the disadvantage of switching when the flow rate is smaller than the predetermined value.

When the predetermined switching condition is satisfied (step S18: YES), the control unit 11 executes control for switching the flow rate to the selected pattern (step S19). When the predetermined switching condition is not satisfied (step S18: NO), the control unit 11 determines whether all patterns have been selected (step S20). When all the patterns have not been selected (step S20: NO), the control unit 11 selects a pattern with the next highest efficiency (step S21), and executes the determination process of step S18. On the other hand, when all the patterns have been selected (step S20: YES), the control unit 11 uniformly sets the flow rate (step S22) and ends the processing illustrated in FIG. 11.

Through the above processing, the control device 10 can perform flow rate control that satisfies the above-described control condition 1 and can improve the efficiency of the entire system.

In step S14, the control unit 11 may additionally perform the following process of changing the switching frequency. For example, the control unit 11 switches the frequency from 10 kHz to 5 kHz when the output of the power converter 20 is 75% or more, and switches the frequency from 5 kHz to 10 kHz when the output of the power converter 20 is 65% or less. However, when the current frequency is greater than 65% and less than 75%, hysteresis is provided, and when the current frequency is 10 kHz, the frequency is set to 10 kHz, and when the current frequency is 5 kHz, the frequency is set to 5 kHz. Note that the value (%) of the ratio of the output to the rated output and the value (kHz) of the frequency are merely examples, and may be arbitrary values.

In step S18, the control unit 11 may additionally execute the following process of varying the refrigerant temperature. That is, the control unit 11 may execute the refrigerant temperature reduction control when the predetermined temperature of any of the power converters 20 is not within the temperature management value although the effect of improving the system efficiency by the predetermined value or more can be expected.

As described above, according to the present embodiment, when the predetermined temperature includes the junction temperature of the power module 21, the control unit 11 can estimate the junction temperature Tj based on the temperature of the refrigerant, the thermal resistance of the power module 21, and the loss of the power module 21 in consideration of the temperature dependency. In addition, the control unit 11 may further control the switching frequency of at least one power module according to the efficiency of each power converter 20. In addition, the control unit 11 can control each flow rate of the refrigerant and control the temperature of the refrigerant.

### Modification Example

The control unit 11 may be included in any of the power converters 20. In this case, the power converter 20 including the control unit 11 also functions as the control device 10, and can control another power converter 20 as a slave by functioning as a master.

### Operations and Effects

According to the control device 10, the control system 1, and the control method of the present embodiment, it is possible to appropriately cool the plurality of power converters 20.

### Other Embodiments

Although the embodiments of the present disclosure have been described in detail with reference to the drawings, the specific configuration is not limited to the embodiments and includes, for example, an amendment to a design that falls within the scope that does not depart from the gist of the present disclosure. For example, the structure of the power converter 20 is not limited to that described with reference to FIGS. 3 to 5, and may be, for example, a rack-mount type, a tower type, or the like using a housing conforming to a standard.

### Computer Configuration

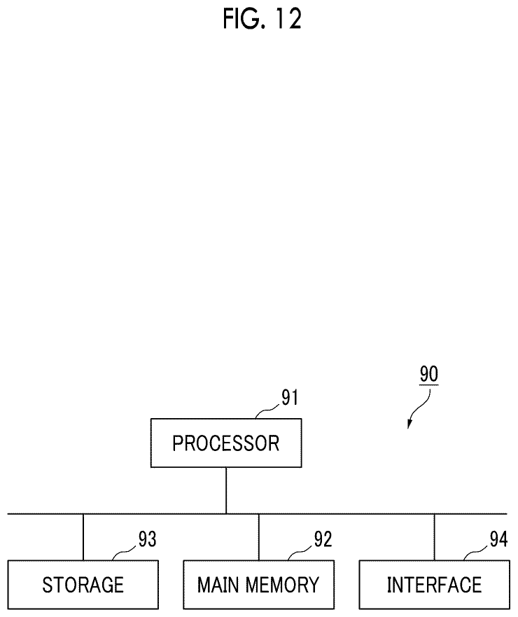

FIG. 12 is a schematic block diagram illustrating a configuration of a computer according to at least one exemplary embodiment.

The computer 90 includes a processor 91, a main memory 92, a storage 93, and an interface 94.

The control device 10, the power converter control device 26, and the like described above are mounted on the computer 90. The operation of each processing unit described above is stored in the storage 93 in the form of a program. The processor 91 reads the program from the storage 93, develops the program in the main memory 92, and executes the above-described processing according to the program. In addition, the processor 91 secures a storage area corresponding to each storage unit described above in the main memory 92 according to the program.

The program may be for realizing a part of the functions to be exhibited by the computer 90. For example, the program may exhibit a function in combination with another program already stored in a storage or in combination with another program installed in another device. In another embodiment, the computer may include a custom large scale integrated circuit (LSI) such as a programmable logic device (PLD)) in addition to or instead of the above configuration. Examples of the PLD include a programmable array logic (PAL), a generic array logic (GAL), a complex programmable logic device (CPLD), and a field programmable gate array (FPGA). In this case, some or all of the functions implemented by the processor may be implemented by the integrated circuit.

Examples of the storage 93 include a hard disk drive (HDD), a solid state drive (SSD), a magnetic disk, a magneto-optical disk, a compact disc read only memory (CD-ROM), a digital versatile disc read only memory (DVD-ROM), and a semiconductor memory. The storage 93 may be an internal medium directly connected to a bus of the computer 90, or may be an external medium connected to the computer 90 via the interface 94 or a communication line. In addition, in a case where the program is distributed to the computer 90 through a communication line, the computer 90 that has received the distribution may develop the program in the main memory 92 and execute the above-described processing. In at least one embodiment, the storage 93 is a non-transitory tangible storage medium.

### Supplementary Notes

The control device 10 described in each embodiment is understood as follows, for example.
(1) A control device 10 according to a first aspect includes a control unit 11 that controls each flow rate of a refrigerant distributed to each of a plurality of power converters 20 each including a power module 21 within a range in which each predetermined temperature of the power converters 20 does not exceed each temperature management value. According to the present aspect and each of the following aspects, the plurality of power converters 20 can be appropriately cooled.
(2) A control device 10 according to a second aspect is the control device 10 of (1), in which the control unit 11 controls the flow rates in accordance with outputs of the power converters 20.
(3) A control device 10 according to a third aspect is the control device 10 of (1). in which the control unit 11 controls the flow rates in accordance with efficiencies of the power converters 20.
(4) A control device 10 according to a fourth aspect is the control device 10 of (1) to (3), in which the predetermined temperature includes a junction temperature of the power module 21, and the control unit 11 estimates the junction temperature based on a temperature of the refrigerant, a thermal resistance of the power module 21, and a loss of the power module 21 in consideration of temperature dependency.
(5) A control device 10 according to a fifth aspect is the control device 10 of (1) to (4), in which the power converter 20 further includes a current sensor 23, a forced air cooling device (fan 25), and a temperature sensor 24 for detecting a temperature in a housing of the power converter, the predetermined temperature includes a temperature of the current sensor 23, and the control unit 11 controls the flow rate and a wind speed of the forced air cooling device based on an ambient temperature detected by the temperature sensor 24 and an operating state of the current sensor 23.
(6) A control device 10 according to a sixth aspect is the control device 10 of (5), in which the power converter 20 further includes a capacitor 22, the predetermined temperature includes a temperature of the capacitor 22, and the control unit 11 controls the flow rate based on a loss of the capacitor 22 and a temperature of the refrigerant, and controls the wind speed of the forced air cooling device based on the ambient temperature.
(7) A control device 10 according to a seventh aspect is the control device 10 of (1) to (6), in which the control unit 11 further controls a switching frequency of at least one of the power modules 21 in accordance with efficiencies of the power converters 20.
(8) A control device 10 according to an eighth aspect is the control device 10 of (1) to (7), in which the control unit 11 controls each flow rate of the refrigerant and controls a temperature of the refrigerant.
(9) A control device 10 according to a ninth aspect is the control device 10 of (1) to (8), in which the control unit 11 is provided in any of the power converters 20.

### INDUSTRIAL APPLICABILITY

According to each aspect of the present invention, it is possible to appropriately cool a plurality of power converters.

### REFERENCE SIGNS LIST

1: control system
10: control device
11: control unit
20, 20A, 20B, 20C, 20D: power converter
21: power module
22: capacitor
23: current sensor
24: temperature sensor
25: fan
26: power converter control device
27: semiconductor element

1. A control device comprising:
a control unit that controls each flow rate of a refrigerant distributed to each of a plurality of power converters each including a power module within a range in which each predetermined temperature of the power converters does not exceed each temperature management value,
wherein the power converter further includes a current sensor, a forced air cooling device, and a temperature sensor for detecting a temperature in a housing of the power converter,
the predetermined temperature includes a temperature of the current sensor, and
the control unit controls the flow rate and a wind speed of the forced air cooling device based on an ambient temperature detected by the temperature sensor and an operating state of the current sensor.

2. The control device according to claim 1,
wherein the control unit controls the flow rates in accordance with outputs of the power converters.

3. The control device according to claim 1,
wherein the control unit controls the flow rates in accordance with efficiencies of the power converters.

4. The control device according to claim 1,
wherein the predetermined temperature includes a junction temperature of the power module, and
the control unit estimates the junction temperature based on a temperature of the refrigerant, a thermal resistance of the power module, and a loss of the power module in consideration of temperature dependency.

5. (canceled)

6. The control device according to claim 1,
wherein the power converter further includes a capacitor,
the predetermined temperature includes a temperature of the capacitor, and
the control unit controls the flow rate based on a loss of the capacitor and a temperature of the refrigerant, and controls the wind speed of the forced air cooling device based on the ambient temperature.

7. The control device according to claim 1,
wherein the control unit further controls a switching frequency of at least one of the power modules in accordance with efficiencies of the power converters.

8. The control device according to claim 1,
wherein the control unit controls each flow rate of the refrigerant and controls a temperature of the refrigerant.

9. The control device according to claim 1,
wherein the control unit is provided in any of the power converters.

10. A control system comprising:
a cooling device for supplying the refrigerant to each of the power converters; and
the control device according to claim 1.

11. A control method comprising:
controlling each flow rate of a refrigerant distributed to each of a plurality of power converters each including a power module within a range in which each predetermined temperature of the power converters does not exceed each temperature management value,
wherein the power converter further includes a current sensor, a forced air cooling device, and a temperature sensor for detecting a temperature in a housing of the power converter,
the predetermined temperature includes a temperature of the current sensor, and
wherein, in the step of controlling, controlling the flow rate and a wind speed of the forced air cooling device based on an ambient temperature detected by the temperature sensor and an operating state of the current sensor.
